(19) United States
(12) Patent Application Publication
(10) Pub. No.: US 2019/0120438 A1
(43) Pub. Date: Apr. 25, 2019

(54) LED MODULE AND LED LIGHT BULB HAVING SAME

(71) Applicant: ZHEJIANG SHENGHUI LIGHTING CO., LTD., Jiaxing (CN)

(72) Inventors: Yehua WAN, Jiaxing (CN); Linzhang LIU, Jiaxing (CN)

(73) Assignee: ZHEJIANG SHENGHUI LIGHTING CO., LTD., Jiaxing (CN)

(21) Appl. No.: 15/772,631

(22) PCT Filed: Jun. 29, 2017
(86) PCT No.: PCT/CN2017/090810

§ 371 Date: May 1, 2018

(30) Foreign Application Priority Data
Jun. 30, 2016 (CN) 201610528168.9

(51) Int. Cl. F21K 9/232; F21K 9/238; H05K 1/02; H05K 1/18; F21V 3/00

(52) U.S. Cl. CPC F21K 9/232; F21K 9/238; F21Y 2107/60; H05K 1/189; F21V 3/00; H05K 1/0209

(57) ABSTRACT

The present disclosure provides an LED light source and an LED light bulb including the LED light source. The LED light source comprises a first LED strip including a first middle portion and first wings positioned at two sides of the first middle portion, and a second LED strip including a second middle portion and second wings positioned at two sides of the second middle portion. Multiple LED chips are disposed on the first wings and the second wings respectively. The first LED strip and the second LED strip are stacked and electrically connected at the first middle portion and the second middle portion. Another aspect of the present disclosure provides an LED light bulb having the LED light source. The first LED strip and the second LED strip are stacked to form an electrical connection.

### CROSS-REFERENCES TO RELATED APPLICATIONS

This application is a national phase entry wider 35 U.S.C. § 371 of International Application No. PCT/CN2017/090810, filed on Jun. 29, 2017. which claims priority of Chinese Patent Application No. 201610528168.9, filed on Jun. 30, 2016, the entire content of which is hereby incorporated by reference.

### FIELD OF THE DISCLOSURE

The present disclosure relates to the field of the LED illumination technology. in particular, it relates to an LED light source and an LED light bulb having the same.

### BACKGROUND

The mainstream LED light bulb designs currently have a few problems. Regarding the appearance, the LED light bulbs have an appearance which is different from the traditional incandescent light bulbs. Further, the current LED light bulbs usually have a narrower angle emission compared to the traditional incandescent light bulbs.

The LED filament style lights may avoid some of the above-identified problems. However, the drawbacks of high cost, complicated processing, low reliability, short life-cycle and inefficient heat dissipation still exist.

### BRIEF SUMMARY OF THE DISCLOSURE

The present disclosure is directed to solve the deficiencies in the prior art. It provides an LED light source with a simple circuit connection, easy assembly, simplified production and wide-angle emission. Accordingly, it provides an LED light bulb which has a low production cost and effective heat dissipation. The LED light bulb can have an appearance similar to the traditional incandescent light bulbs with wide-angle emission.

The present disclosure provides an LED light source which comprises: a first LED strip including a first middle portion and first wings positioned at two sides of the first middle portion, a plurality of LED chips being disposed on the first wings; and a second LED strip including a second middle portion and second wings positioned at two sides of the second middle portion, a plurality of LED chips being disposed on the second wings, wherein the first LED strip and the second LED strip are stacked and electrically connected at the first middle portion and the second middle portion.

Optionally, an angle between each of the first wings and the first middle portion may be no less than 90 degrees, and an angle between each of the second wings and the second middle portion may be no less than 90 degrees.

Optionally, the angle between each of the first wings and the first middle portion may be approximately 90 degrees, and the angle between each of the second wings and the second middle portion may be approximately 90 degrees. In such an arrangement, the LED light source is formed as a rectangular prism.

In consideration of illumination, optionally, an uncovered one from the first middle portion and the second middle portion may be disposed with at least one LED chip.

In one instance, the first middle portion may be stacked on top of the second middle portion, and the at least one LED chip may be disposed on the first middle portion. In another instance, the first middle portion may be stacked on top of the second middle portion, the at least one LED chip may be disposed on the second middle portion, and the first middle portion may be provided with a hollow-out to expose the at least one LED chip on the second middle portion. The stacked first and second middle portions enable an electrical connection without affecting disposal and illumination of the LED chips.

Optionally, the first middle portion, the second middle portion, the first wings and the second wings may be in a rectangular shape respectively. In one instance, two sides of the first middle portion may be spaced from the first wings, and the first middle portion may be connected to the first wings by a first flexible circuit board, and the plurality of the LED chips may be provided on the first flexible circuit board. By means of the flexible circuit boards, the middle portions and the wings are connected, and an electrical connection as well as shaping flexibility are easily realized. In a similar manner, two sides of the second middle portion may be spaced from the second wings, the second middle portion may be connected to the second wings by a second flexible circuit board, and the plurality of the LED chips may be provided on the second flexible circuit board.

Another aspect of the present disclosure provides an LED light bulb which comprise: at least one LED light source including a first LED strip having a plurality of LED chips, a second LED strip having a plurality of LED chips, and the first LED strip and the second LED strip being stacked; a driver arranged in an electrical connection with the at least one LED light source to drive and control the at least one LED light source to emit light; a base electrically connecting the driver to an outside power source; a heat sink for supporting the at least one LED light source and dissipating heat generated by the at least one LED light source; and a housing joined to the based to define a space to accommodate the at least one LED light source, the heat sink and the driver to integrate as the claimed LED light bulb.

Optionally, the present disclosure may comprise an insulator provided at one end of the heat sink, wherein the heat sink may be made of an aluminum material, and the insulator and the base may be joined to provide an electrical insulation between the heat sink and the base. In this case, the insulator and the heat sink may be combined by a plastic-aluminum injection molding process.

The heat sink may further comprise a supporting portion to receive and support the at least one LED light source, the supporting portion may be a rectangular prism including a top face for supporting the first middle portion and the second middle portion as stacked and side faces, and at least one of the side faces may be in contact with the first wings or the second wings.

To achieve an electrical connection, optionally, the heat sink may further comprise a hole in the body, the at least one LED light source may comprise a pin socket electrically connecting the LED chips, and the driver may comprise pins, so that the pins pass through the hole and are inserted into the pin socket for an electrical connection between the at least one LED light source and the driver.

To secure the driver, optionally, the heat sink may further comprise two guiding grooves on an inner wall to receive and fasten two sides of the driver.

In light of a short circuit between the driver and other components, optionally, the present disclosure may comprise a protection cover, wherein the protection cover may include a body and hook slots at two ends of the body, and two sides of the driver may be inserted into the hook slots of the protection cover.

In order to further increase emission angle, the housing may be made of a non-transparent glass material, and the housing and the base may be glued together.

Compared to the conventional skills, the present disclosure provides an LED light source, in which a first LED strip and a second LED strip are stacked to obtain a contact, thereby achieving an electrical connection. There is no need for an additional circuit connection. Meanwhile, first wings and second wings are folded respectively to enable the first LED strip and the second LED strip maintained in a big angle to achieve wide-angle emission. In such way, it increases production operability, simplifies the production and reducing production cost.

Moreover, the present disclosure provides an LED light bulb having the LED light source. The LED light bulb comprises the housing to provide a diffusion and reflection on light emitted from the LED light source. The housing is integrated to the base to form an appearance similar to the traditional light sources. The driver is inserted into the heat sink and an electrical connection is easily obtained by inserting the pins to the pin socket of the LED light source.

### BRIEF DESCRIPTION OF THE DRAWINGS

The following drawings are merely examples for illustrative purposes according to various disclosed embodiments and are not intended to limit the scope of the present disclosure in any way.

FIG. 1 is a front view of an LED light bulb consistent with the present disclosure;

FIG. 2 is a partial sectional view of the LED light bulb as illustrated in FIG. 1 consistent with the present disclosure;

FIG. 3 is a vertical sectional view of the LED light bulb as illustrated in FIG. 1 consistent with the present disclosure;

FIG. 4 is a perspective view of a heat sink and a supporting portion consistent with the present disclosure;

FIG. 5 is an exploded view of the LED light bulb consistent with the present disclosure;

FIG. 6 is another exploded view of the LED light bulb viewed from an angle different from FIG. 5; and

FIG. 7 is an exploded view of the LED light source consistent with the present disclosure.

### DETAILED DESCRIPTION

Detailed descriptions and technical contents according to embodiments of the present disclosure will be described with reference to the accompanying drawings shown below. In addition, the drawings are not necessarily prepared in an actual proportion. It is apparent that the proportions of the drawings are not intended to limit the scope of the present disclosure as claimed.

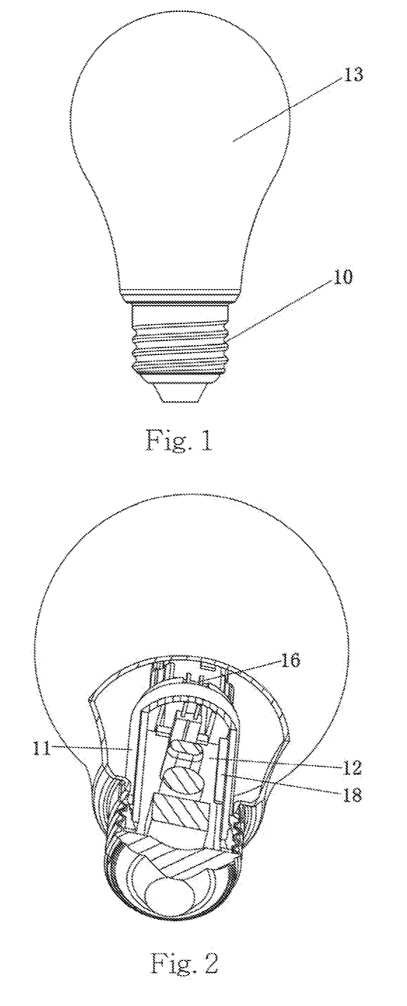

As illustrated in FIGS. 1-7, one aspect of the present disclosure provides a Light Emitting Diode (LED) light bulb, which comprises a base 10, a heat sink 11, a driver 12, a housing 13 and at least one LED light source 50. The housing 13 is joined to the based 10 to form an inner space to accommodate the heat sink 11, the driver 12 and the LED light source 50. In consideration of enhancing diffusion effect, the housing 13 is not transparent and made of a glass material. In one instance, the housing 13 and the base 10 are glued together. The driver 12 has an electrical connection with the LED light source 50 to drive and control the LED light source 50 to emit light. The LED light source 50 provides a light source.

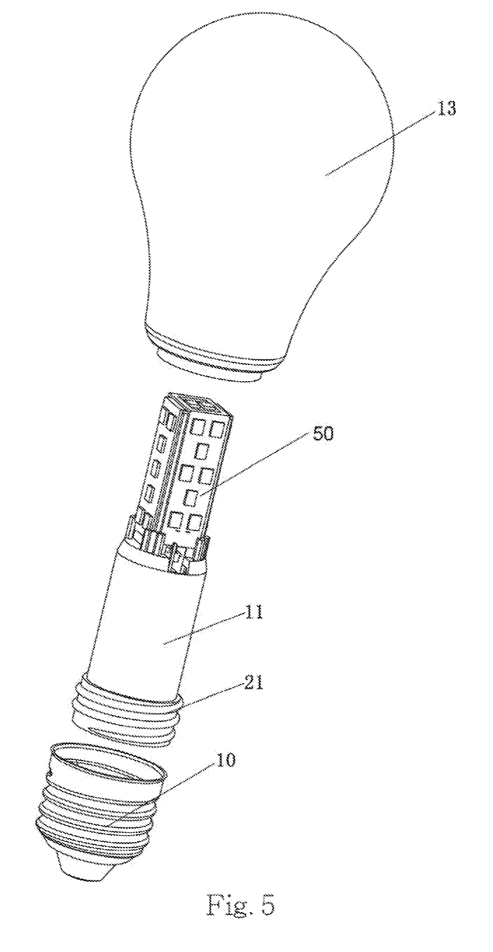

In reference to FIGS. 5-7, another aspect of the present disclosure provides an LED light source. The LED light source 50 comprises a first LED strip 1 and a second LED strip 2. The first LED strip 1 includes a first middle portion 3, first wings 4 and a first flexible circuit board 8. Preferably, the first wings 4 are folded and each wing of the first wings 4 is positioned symmetrically at two sides of the first middle portion 3. A plurality of LED chips 5 are disposed on the first wings 4. The second LED strip 2 includes a second middle portion 6, second wings 7 and a second flexible circuit board 9, and a plurality of LED chips 5 are disposed on the second wings 7. Similar to the arrangement of the first wings 4, the second wings 7 are folded and each wing of the second wings 7 is positioned symmetrically at two sides of the second middle portion 6.

Further, the LED strip I and the second LED strip 2 are stacked and, cross-stacked and electrically connected at the first middle portion 3 and the second middle portion 6. In one instance, the first middle portion 3 and the second middle portion 6 are connected by the process of spot welding.

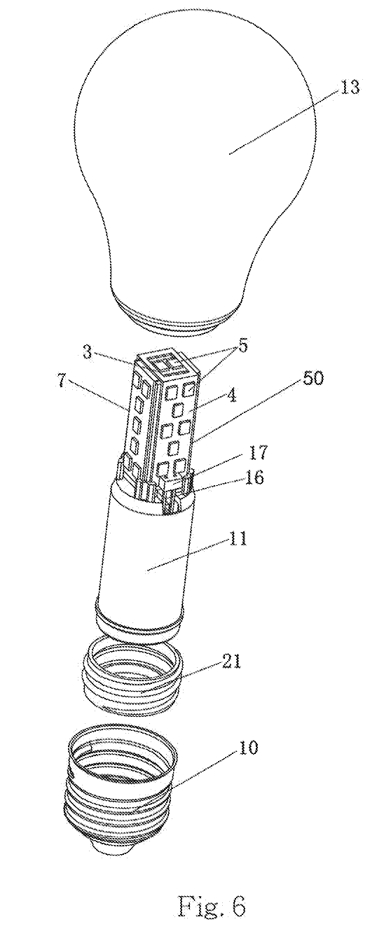

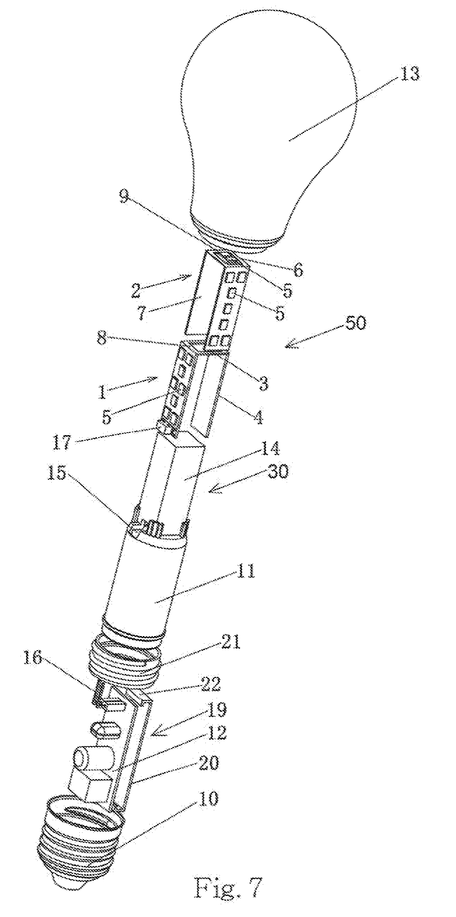

As illustrated in FIG. 7, an angle between each wing of the first wings 4 and the first middle portion 3 is no less than 90 degrees, while an angle between each wing of the second wings 7 and the second middle portion 6 is no less than 90 degrees. In one instance, the angle of each wing of the first wings 4 and the first middle portion 3 is approximately perpendicular, while the angle between each wing of the second wings 7 and the second middle portion 6 is approximately perpendicular. When being stacked at the middle portions 3 and 6, an uncovered middle portion (either top or bottom) is provided with at least one LED chip 5 for more illumination. In one instance, as shown in FIG. 6, when the first middle portion 3 is stacked on top of the second middle portion 6, the at least one LED chip 5 is disposed on the second middle portion 6 at bottom, and the first middle portion 3 is provided with a hollow-out to expose the at least one LED chip 5 of the uncovered second middle portion 6 at bottom. In another instance, when the first middle portion 3 is stacked on top of the second middle portion 6, the first middle portion 3 on top is provided the at least one LED chip 5.

The middle portions 3 and 6 can be in a rectangular shape, and each wing of the wings 4 and 7 can also be in a rectangular shape. The LED chips 5 are placed on the flexible circuit boards 8 and 9 and disposed on the wings 4 and 7 and the uncovered middle portions 3 and 6. In one instance, the wings are formed by bending at two sides of middle portion and thus connected to the middle portion. In another instance, the middle portion and the corresponding wings are separated with a space and connected by the corresponding flexible circuit board. More specifically, two sides of the first middle portion 3, adjacent to the first wings 4, are spaced from the first wings 4, and the first middle portion 3 and the first wings 4 are connected by the first flexible circuit board 8. And two sides of the second middle portion 6, adjacent to the second wings 7, are spaced from the second wings 7, and the second middle portion 6 and the second wings 7 are connected by the second flexible circuit board 9, The LED chips 5 are disposed on the first flexible circuit board 8 and the second flexible circuit board 9 respectively.

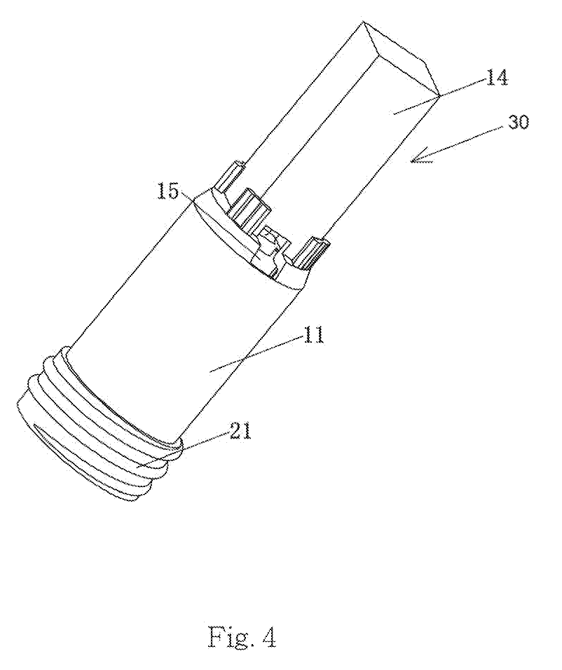

A body of the heat sink 11 is, in a cylindrical configuration, which is hollow. The driver 12 is a driver circuit board and is disposed inside the heat sink 11. As illustrated in FIG. 4, the heat sink 11 comprises a supporting portion 30 for receiving and supporting the LED light source 50. In one instance, the supporting portion 30 may be hollow and may have a configuration matching to that of the LED light source 50 for a fit. The LED light source 50 is shelved onto the supporting portion 30 and the heat sink 11 to provide a multi-faced lighting source.

More specifically, the heat sink 11 can be made of metal, ceramics, or plastic material of certain heat dissipation ability. In one instance, the heat sink 11 is made of an aluminum material, and the LED light bulb further comprises an insulator 21 disposed at one end of the heat sink 11. The insulator 21 is made of a thermal-conducting plastic. In one instance, the insulator 21 and the base 10 are screwed to combine to provide an electrical insulation between the heat sink 11 and the base 10. In this case, the insulator 21 and the heat sink 11 can be combined by a plastic-aluminum injection molding process. In another instance, the heat sink 11 is made of a thermal-conducting plastic, and, in this case, the heat sink 11 can be directly joined to the base 10.

In some embodiments, the supporting portion 30 of the heat sink 11 is a rectangular prism or other cuboids. In this configuration, the supporting portion 30 includes a top face to contact and support the middle portions 3 and 6 of the LED light source 50, and at least one side face in contact with the wings 4 and 7. The side faces are comprised of four enclosing planes 14. In some embodiments, the wings 4 and 7 of the LED light source 50 are in contact with the corresponding planes 14.

As illustrated in FIGS. 4 and 7, a hole 15 is through the body of the heat sink 11, at one end of the supporting portion 30 remote from the LED light source 50. The driver 12 comprises pins 16, while the LED light source 50 comprises a pin socket 17 at an end adjacent to the driver 12. The pin socket 17 is disposed on one of the flexible circuit boards 8, 9 and electrically connects the LED chips 5. In one embodiment, the pins 16 of the driver 12 pass through the hole 15 and are inserted into the pin socket 17 of the LED light source 50 to establish an electrical connection between the driver 12 and the LED light source 50.

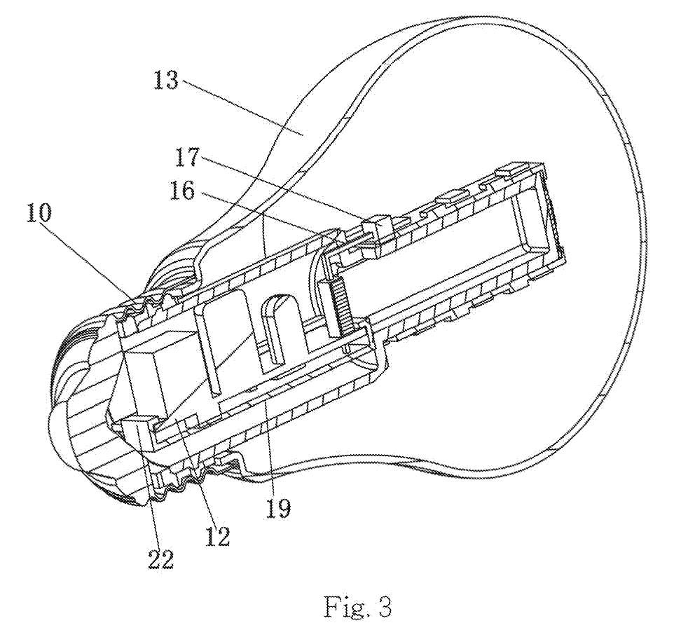

FIG. 2 is a cross-sectional view partially showing an internal structure of the LED light bulb. As illustrated, two guiding grooves 18 are provided on an inner wall of the heat sink 11. When the driver 12 is inserted into the heat sink 11, the guiding grooves 18 receive and fasten two sides of the driver 12. In one instance, the two guiding grooves 18 are symmetrically disposed inside the heat sink 11.

Moreover, as illustrated in FIGS. 3 and 7, the LED light bulb further comprises a protection cover 19 as provided to hook with the driver 12 for a protection. More specifically, the protector cover 19 comprises a body 20 and hook slots 22 at two ends of the body 20. From a side view, each of the hook slots 22 forms an L-shape. Two sides of the driver 12 are inserted into the hook slots 22 of the protection cover 19 for the protection.

In some embodiments, the LED light source 50 may include more than two LED strips. For example, the LED light source 50 may include three LED strips. Each LED strip includes two wings to hold the LED chips, and a middle portion similar to middle portions 3 or 6. The middle portions of the LED strips may be electrically connected. The middle portions of the LED strips may be fixed on the supporting portion 30 or the top face of the supporting portion 30. The supporting portion 30 may be a hexagonal shape, which provides supporting surfaces for the six wings of the three LED strips. In another example, the LED light source 50 may include four LED strips. Each LED strip includes two wings to hold the LED chips, and a middle portion similar to middle portions 3 or 6. The middle portions of the LED strips may be electrically connected. The middle portions of the LED strips may be fixed on the supporting portion 30 or the top face of the supporting portion 30. The supporting portion 30 may be an octagonal shape, which provides supporting surfaces for the eight wings of the three LED strips.

In some embodiments, the LED light source 50 may include straight LED wings/strips, curved wings/strips, or jagged wings/strips. In some embodiments, the supporting portion 30 may be of a cylinder or a cone shape. The LED wings 4 and 7 may be curvy strips and may be supported by the supporting portion 30.

While the present disclosure has been particularly described in terms of the various forms and examples, the forms and examples do not recite all details and should not be used to limit the present disclosure. They are applied for a better explanation. There might be alternative, modifications and variations. And it is to be understood that many alternatives, modifications and variations will be apparent to those skilled in the art in light of the foregoing description. It is therefore contemplated that the appended claims will embrace any such alternatives, modifications and variations as falling within the true scope and spirit of the present disclosure.

What is claimed is:

1. An LED light source, comprising:
a first LED strip including a first Middle portion and first wings positioned at two sides of the first middle portion, a plurality of LED chips being disposed on the first wings; and
a second LED strip including a second middle portion and second wings positioned at two sides of the second middle portion, a plurality of LED chips being disposed on the second wings; wherein:
the first LED strip and the second LED strip are stacked and electrically connected at the first middle portion and the second middle portion.

2. The LED lighting source according to claim 1, wherein an angle between each of the first wings and the first middle portion is no less than 90 degrees, and an angle between each of the second wings and the second middle portion is no less than 90 degrees.

3. The LED lighting source according to claim 1, wherein the angle between each of the first wings and the first middle portion is approximately 90 degrees, and the angle between each of the second wings and the second middle portion is approximately 90 degrees.

4. The LED lighting source according to claim 1, wherein one of the first middle portion and the second middle portion is exposed and disposed with an LED chip.

5. The LED lighting source according to claim 4, wherein the first middle portion is stacked on top of the second middle portion, and the at least one LED chip is disposed on the first middle portion.

6. The LED lighting source according to claim 4, wherein the first middle portion is stacked on top of the second middle portion, the at least one LED chip is disposed on the second middle portion, and the first middle portion includes a hollow-out to expose the at least one LED chip on the second middle portion.

7. The LED lighting source according to claim 1, wherein the first middle portion, the second middle portion, the first wings and the second wings are of a rectangular shape.

8. The LED lighting source according to claim 1, wherein two sides of the first middle portion are spaced from the first wings, and the first middle portion is connected to the first wings by a first flexible circuit board, and the plurality of the LED chips are provided on the first flexible circuit board.

9. The LED lighting source according to claim 1, wherein two sides of the second middle portion are spaced from the second wings, the second middle portion is connected to the second wings by a second flexible circuit board, and the plurality of the LED chips are provided on the second flexible circuit board.

10. An LED light bulb, comprising:
a LED light source, including a first LED strip having a plurality of LED chips, a second LED strip having a plurality of LED chips, and the first LED strip and the second LED strip being stacked;
a driver arranged in an electrical connection with the LED light source to drive and control the LED light source to emit light;
a base electrically connecting the driver to an outside power source;
a heat sink for supporting the LED light source and dissipating heat generated by the LED light source; and
a housing coupled to the based to accommodate the LED light source, the heat sink and the driver.

11. The LED light bulb according to claim 10, further comprising an insulator provided at one end of the heat sink, wherein the heat sink is made of an aluminum material, and the insulator and the base are coupled to provide an electrical insulation between the heat sink and the base.

12. The LED light bulb according to claim 11, wherein the insulator and the heat sink are combined by a plastic-aluminum injection molding process.

13. The LED light bulb according to claim 10, wherein the heat sink further comprises a supporting portion to support the LED light source, the supporting portion is a rectangular protrusion including a top face and side faces, the top face supporting the first middle portion and the second middle portion and at least one of the side faces is in contact with the first wings or the second wings.

14. The LED light bulb according to claim 10, wherein the heat sink further comprises a hole in the body, the LED light source comprises a pin socket electrically connecting the LED chips, and the driver comprises pins, wherein the pins pass through the hole and are inserted into the pin socket to form an electrical connection between the LED light source and the driver.

15. The LED light bulb according to claim 10, wherein the heat sink further comprises two guiding grooves on an inner wall to receive two sides of the driver.

16. The LED light bulb according to claim 10, further comprising a protection cover, wherein the protection cover includes a body and hook slots at two ends of the body, and two sides of the driver are inserted into the hook slots of the protection cover.

17. The LED light bulb according to claim 10, wherein the housing is made of a non-transparent glass material, and the housing and the base are joined by glue.
